(19) United States
(12) Patent Application Publication
(10) Pub. No.: US 2021/0238374 A1
(43) Pub. Date: Aug. 5, 2021

(54) TEMPLATED SYNTHESIS OF NANOVOIDED POLYMERS

(71) Applicant: Facebook Technologies, LLC, Menlo Park, CA (US)

(72) Inventors: Sheng Ye, Redmond, WA (US); Renate Eva Klementine Landig, Seattle, WA (US); Kenneth Alexander Diest, Kirkland, WA (US); Andrew John Ouderkirk, Kirkland, WA (US); Charles Robert Bowman, St. Paul, MA (US); Robert G. Bowman, Woodbury, MN (US); William Arthur Hendrickson, Woodury, MN (US); Christopher J. Rueb, St. Paul, MN (US); Lafe Joseph Purvis, II, Redmond, WA (US); Wenmo Sun, Redmond, WA (US); Ryan Li, New York, NY (US); Oleg Yaroshchuk, Redmond, WA (US); Tingling Rao, Bellevue, WA (US); Arman Boromand, Redmond, WA (US); Churning Zhao, Bellevue, WA (US); Morteza Khaleghimeybodi, Bothell, WA (US)

(21) Appl. No.: 17/142,599

(22) Filed: Jan. 6, 2021

Related U.S. Application Data
(60) Provisional application No. 62/969,967, filed on Feb. 4, 2020.
(60) Provisional application No. 63/051,573, filed on Jul. 14, 2020.

(51) Int. Cl. C08J 9/00; H01L 41/09; H01L 41/193; H01L 41/45

(52) U.S. Cl. CPC C08J 9/0014; H01L 41/09; H01L 41/193; H04R 31/00; C08J 2201/0502; C08J 2300/00; H01L 41/45

(57) ABSTRACT

A method of forming a voided polymer includes forming a polymerizable composition containing a polymer precursor and a solid templating agent, forming a coating of the polymerizable composition, processing the coating to form a cured polymer material having a solid phase in a plurality of defined regions, and removing at least a portion of the solid phase from the cured polymer material to form a voided polymer layer.

### CROSS-REFERENCE TO RELATED APPLICATIONS

This application claims the benefit of priority under 35 U.S.C. § 119(e) of U.S. Provisional Application No. 62/969,967, filed Feb. 4, 2020, and U.S. Provisional Application No. 63/051,573, filed Jul. 14, 2020, the contents of which are incorporated herein by reference in their entirety.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 shows an example method for manufacturing a nanovoided polymer (NVP) layer according to certain embodiments.

FIG. 2 shows an example method for manufacturing a nanovoided polymer layer having an overlying capping layer according to certain embodiments.

FIG. 3 is a schematic illustration showing example multilayer stacks including one or more nanovoided polymer layers according to some embodiments.

FIG. 4 is a schematic illustration of an electroded NVP stack according to some embodiments.

FIG. 5 depicts an example manufacturing method for forming a nanovoided polymer-based actuator according to various embodiments.

FIG. 6 shows a scanning electron microscope (SEM) image of a voided polymer according to some embodiments.

FIG. 7 is a higher magnification view of a portion of the SEM image of FIG. 6 according to some embodiments.

FIG. 8 depicts an example vapor deposition process for forming an organic epitaxial layer according to some embodiments.

FIG. 9 illustrates the processing of a two-domain polymer thin film according to certain embodiments.

FIG. 10 shows example multilayer structures according to various embodiments.

FIGS. 11-17 depict example vaporizable and crystallizable templating agents according to certain embodiments.

FIG. 18 is an illustration of exemplary augmented-reality glasses that may be used in connection with embodiments of this disclosure.

FIG. 19 is an illustration of an exemplary virtual-reality headset that may be used in connection with embodiments of this disclosure.

FIG. 20 is an illustration of exemplary haptic devices that may be used in connection with embodiments of this disclosure.

FIG. 21 is an illustration of an exemplary virtual-reality environment according to embodiments of this disclosure.

FIG. 22 is an illustration of an exemplary augmented-reality environment according to embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

Polymer materials may be incorporated into a variety of different optic and electro-optic device architectures, including active and passive optics and electroactive devices. Electroactive polymer (EAP) materials, for instance, may change their shape under the influence of an electric field. EAP materials have been investigated for use in various technologies, including actuation, sensing and/or energy harvesting. Lightweight and conformable, electroactive polymers may be incorporated into wearable devices such as haptic devices and are attractive candidates for emerging technologies including virtual reality/augmented reality devices where a comfortable, adjustable form factor is desired.

Virtual reality (VR) and augmented reality (AR) eyewear devices or headsets, for instance, may enable users to experience events, such as interactions with people in a computer-generated simulation of a three-dimensional world or viewing data superimposed on a real-world view. VR/AR eyewear devices and headsets may also be used for purposes other than recreation. For example, governments may use such devices for military training, medical professionals may use such devices to simulate surgery, and engineers may use such devices as design visualization aids.

These and other applications may leverage one or more characteristics of thin film polymer materials, including the refractive index to manipulate light and/or in the example of electroactive applications, electrostatic forces to generate compression between conductive electrodes. In some embodiments, the electroactive response may include a mechanical response to an electrical input that varies over the spatial extent of the device, with the electrical input being applied by a control circuit to a layer of electroactive material located between paired electrodes. The mechanical response may be termed an actuation, and example devices may be, or include, actuators.

In particular embodiments, a deformable optical element and an electroactive layer may be co-integrated whereby the optical element may itself be actuatable. Deformation of the electroactive polymer may be used to actuate optical elements in an optical assembly, such as a lens system. Notwithstanding recent developments, it would be advantageous to provide electroactive polymer materials having improved characteristics, including a controllable deformation response and/or a tunable refractive index in an optically transparent package.

The present disclosure is generally directed to the formation of voided polymer materials including nanovoided polymers (NVPs). The voided polymer may be an elastomer, for example. In particular embodiments, voided polymer materials may be formed from a polymerizable composition containing a homogeneous solution of a polymer precursor and a solid templating agent. The polymerizable composition may be deposited from a vapor as a layer or thin film onto a substrate as a blanket layer or in a pre-defined pattern. Curing of the deposited layer, e.g., with actinic radiation, may induce crosslinking of a polymer matrix and phase separation between the polymer and the templating agent. A subsequent processing step, which may include one or more of a change in temperature, pressure, etc., may be used to sublime and remove the solid templating agent from the nascent polymer matrix, and form a voided polymer layer. The instant disclosure relates also to optical elements that include one or more voided polymer layers.

In some examples, an “optical element” may include a structured article configured to interact with light, and may include, without limitation, refractive optics, reflective optics, dispersive optics, polarization optics, or diffractive optics. A voided polymer layer may be incorporated into a structured, or patterned layer. A “structured layer” may, in some examples, include a voided polymer layer having features, i.e., periodic features, that may have a characteristic dimension (I) in at least one direction that is less than the wavelength (λ) of light that interacts with the optical element, e.g., 1<0.5λ, 1<0.2λ, or 1<0.1λ.

According to some embodiments, a voided polymer may be actuated to control the size and shape of the voids therein. Control of the void geometry, as well as the overall geometry of a voided polymer layer, can be used to control the mechanical, optical, and other properties of an optical element. For instance, a voided polymer layer may have a first effective refractive index in an unactuated state and a second effective refractive index different than the first refractive index in an actuated state.

In contrast to traditional optical materials that may have either a static index of refraction or an index that can be switched between two static states, voided polymers including nanovoided polymers represent a class of optical materials where the index of refraction can be tuned over a range of values to advantageously control the interaction of these materials with light.

In connection with some embodiments, a voided (e.g., nanovoided) polymer may be incorporated into an acoustic element such as a loudspeaker to increase the acoustic volume. Such a polymer material may improve acoustic performance (especially bass performance) of a loudspeaker system. It can also allow the speaker enclosure to be further miniaturized while providing the same loudness. The voided or nanovoided polymer may be freely dispersed in a loudspeaker chamber, for example, or located at an internal wall of a loudspeaker chamber. In some embodiments, a voided or nanovoided polymer may be treated by a surfactant to control the electron density at the inner surfaces of the voids and accordingly improve adsorption and desorption performance. The voided or nanovoided polymers, which may include a broad range of void sizes from nanometers to micrometers, may be implemented to provide a better response to different wavelengths of sound and provide an effective response in the broadband audio frequencies (e.g., 20 Hz to 20 kHz).

In connection with some embodiments, a voided (e.g., nanovoided) polymer may be incorporated into an in-ear device (such as a hearable device or inside the earplug of a hearing aid) to decrease environmental sound pressure incident on a user's eardrum (i.e., to improve the acoustic passive attenuation of the device). Improved passive attenuation of the device can also improve the maximum stable gain (MSG) of the system by mitigating the feedback that typically occurs at higher gain outputs of a hearable device or hearing aid.

In accordance with various embodiments, a voided polymer material may include a polymer matrix and a plurality of voids dispersed throughout the matrix. The polymer matrix material may include a deformable, electroactive polymer such as polydimethylsiloxane, acrylates, urethanes, or polyvinylidene fluoride and its copolymers, as well as mixtures of the foregoing. Such materials, according to some embodiments, may have a dielectric constant or relative permittivity, such as, for example, a dielectric constant ranging from approximately 1.2 to approximately 30.

As used herein the terminology “nanovoids,” “nanoscale voids,” “nanovoided,” and the like, may refer to voids having at least one sub-micron dimension, i.e., a length and/or width and/or depth, of less than approximately 1000 nm. In some embodiments, the average void size may be between approximately 2 nm and approximately 1000 nm (e.g., approximately 2 nm, approximately 5 nm, approximately 10 nm, approximately 20 nm, approximately 30 nm, approximately 40 nm, approximately 50 nm, approximately 60 nm, approximately 70 nm, approximately 80 nm, approximately 90 nm, approximately 100 nm, approximately 110 nm, approximately 120 nm, approximately 130 nm, approximately 140 nm, approximately 150 nm, approximately 160 nm, approximately 170 nm, approximately 180 nm, approximately 190 nm, approximately 200 nm, approximately 250 nm, approximately 300 nm, approximately 400 nm, approximately 500 nm, approximately 600 nm, approximately 700 nm, approximately 800 nm, approximately 900 nm, or approximately 1000 nm, including ranges between any of the foregoing values).

In certain embodiments, the voided polymers disclosed herein may include nanovoided polymers as well as polymers with voids having a larger average pore size, i.e., up to approximately 20 μm, e.g., approximately 1 μm, approximately 2 μm, approximately 5 μm, approximately 10 μm, or approximately 20 μm, including ranges between any of the foregoing values.

In example voided polymers, the voids or nanovoids may be randomly distributed throughout the polymer matrix, without exhibiting any long-range order, or the voids or nanovoids may exhibit a structured architecture, including a regular, periodic structure having a regular repeat distance of approximately 20 nm to approximately 1000 nm. In both disordered and ordered structures, the voids may be discrete, closed-celled voids, open-celled voids that may be at least partially interconnected, or combinations thereof. For open-celled voids, the void size (d) may be the minimum average diameter of the cell. The voids may be any suitable size, and in some embodiments, the voids may approach the scale of the thickness of a voided polymer layer.

In certain embodiments, as determined by scanning electron microscopy, the voids may occupy approximately 5% to approximately 75% by volume of the voided polymer matrix, e.g., approximately 5%, approximately 10%, approximately 20%, approximately 30%, approximately 40%, approximately 50%, approximately 60%, approximately 70%, or approximately 75%, including ranges between any of the foregoing values.

According to some embodiments, the voids may be substantially spherical, although the void shape is not particularly limited. For instance, in addition to, or in lieu of spherical voids, the voided polymer material may include voids that are oblate, prolate, lenticular, ovoid, etc., and may be characterized by a convex and/or a concave cross-sectional shape. The void shape may be isotropic or anisotropic. Moreover, the topology of the voids throughout the polymer matrix may be uniform or non-uniform. As used herein “topology” with reference to the voids refers to their overall arrangement within the polymer matrix and may include their size and shape as well as their respective distribution (density, periodicity, etc.) throughout the polymer matrix. By way of example, the size of the voids and/or the void size distribution may vary as a function of position within the voided polymer material.

According to various embodiments, voids may be distributed homogeneously or non-homogeneously. By way of example, the size of the voids and/or the void size distribution may vary spatially within the voided polymer material, i.e., laterally and/or with respect to the thickness of a layer of the voided polymer material. In a similar vein, a voided polymer thin film may have a constant density of voids or the density of voids may increase or decrease as a function of position, e.g., thickness of a voided polymer layer. Adjusting the void fraction of an EAP, for instance, can be used to tune its compressive stress-strain characteristics or its effective refractive index.

In some embodiments, the voids may be at least partially filled with a gas. A fill gas may be incorporated into the voids to suppress electrical breakdown of an electroactive polymer element (for example, during capacitive actuation). The gas may include air, nitrogen, oxygen, argon, sulfur hexafluoride, an organofluoride and/or any other suitable gas. In some embodiments, such a gas may have a high dielectric strength. In some embodiments, the fill gas composition may be selected to tune the optical properties of the voided polymer, including the scattering, reflection, absorption, and/or transmission of light.

In some embodiments, the application of a voltage to a voided polymer layer may change the internal pressure of a fill gas located within the voided regions thereof. In this regard, a fill gas may diffuse either into or out of the voided polymer matrix during dimensional changes associated with its deformation. Such changes in void topology can affect, for example, the hysteresis of an electroactive device incorporating the electroactive polymer during dimensional changes, and also may result in drift when the voided polymer layer's dimensions are rapidly changed.

In some embodiments, the voided polymer may be characterized by an elastic modulus of from approximately 0.2 MPa to approximately 500 MPa. In some embodiments, the voided polymer material may include an elastomeric polymer matrix having an elastic modulus of less than approximately 100 MPa (e.g., approximately 100 MPa, approximately 50 MPa, approximately 20 MPa, approximately 10 MPa, approximately 5 MPa, approximately 2 MPa, approximately 1 MPa, approximately 0.5 MPa, or approximately 0.2 MPa, including ranges between any of the foregoing values). In some embodiments, the voided polymer material may include an elastomeric polymer matrix having an elastic modulus of at least approximately 0.2 MPa. That is, in some embodiments, the voided polymer material may exhibit sufficient rigidity to avoid collapse or other unwanted deformation, e.g., during its formation or subsequent processing.

Polymer materials including voids having nanoscale dimensions may possess a number of advantageous attributes. For example, the incorporation of nanovoids into a polymer matrix may augment the permittivity of the resulting composite. Furthermore, the high surface area-to-volume ratio associated with nanovoided polymers will provide a greater interfacial area between the nanovoids and the surrounding polymer matrix. With such a high surface area structure, electric charge can accumulate at the void-matrix interface, which can enable greater polarizability and, consequently, increased permittivity (Eᵣ) of the composite. Additionally, because ions, such as plasma electrons, can only be accelerated over small distances within voids having nanoscale dimensions, the likelihood of molecular collisions that liberate additional ions and create a breakdown cascade is decreased, which may result in the nanovoided material exhibiting a greater breakdown strength than un-voided or even macro-voided polymers. In some embodiments, an ordered nanovoided architecture may provide a controlled deformation response, while a disordered nanovoided structure may provide enhanced resistance to crack propagation and thus improved mechanical durability.

As disclosed herein, a printing, vapor deposition, or other deposition method may be used to form voided polymer materials, such as nanovoided polymer thin films or structured layers. Methods of forming voided polymer thin films or structured layers may include depositing a polymerizable composition containing a polymer precursor and a solid templating agent, curing the polymer precursor to form a polymer matrix, and then removing the templating agent from the polymer matrix by sublimation. Example methods for forming a coating of the polymerizable composition on a substrate include extruding and printing (e.g., inkjet printing or gravure printing), vapor deposition (e.g., physical vapor deposition (PVD), chemical vapor deposition (CVD), initiated chemical vapor deposition (i-CVD), and the like), although additional deposition methods are contemplated, such as spin coating, spray coating, dip coating, and doctor blading.

In accordance with various embodiments, an example method may include (i) depositing a solution (i.e., a polymerizable composition) including a curable material and at least one templating agent, (ii) processing the deposited solution to form a cured polymer material having discrete regions of the solid templating agent, and (iii) removing at least a portion of the solid templating agent from the cured polymer material to form a voided polymer material on the substrate.

A variety of precursor chemistries may be used to form a polymerizable composition. According to some embodiments, the polymer precursor may include one or more multi-functional vinyl-containing (unsaturated double bond-containing) molecules, or a mixture of mono-functional vinyl containing molecules and multi-functional vinyl containing molecules. Example vinyl-containing species include allyls, (meth)acrylates, fluoro-(meth)acrylates, (meth)acrylate terminated, vinyl-terminated or allyl-terminated fluoro-(pre)polymers, silicone-(meth)acrylates, (meth)acrylate terminated, vinyl-terminated or allyl-terminated silicone-(pre)polymers, (meth)acrylate terminated, vinyl-terminated or allyl-terminated polydimethylsiloxanes, urethane (meth)acrylates, (meth)acrylate terminated, vinyl-terminated or allyl-terminated urethane-(pre)polymers, ethylene glycol (meth)acrylates, (meth)acrylate terminated, vinyl-terminated or allyl-terminated ethylene glycol-(pre)polymers, (meth)acrylate terminated, vinyl-terminated or allyl-terminated thiolether-(pre)polymers, aliphatic (meth)acrylates, acrylonitriles, and styrenics. As used herein, the designation “(meth)acrylate” or “(meth)acrylates” refers collectively to acrylate and/or methacrylate compositions. For example, a polymer precursor that includes a urethane (meth)acrylate may include one or both of a urethane acrylate and a urethane methacrylate.

Example vinyl molecules include 2,2,3,3,4,4,5,5-octafluoropentyl (meth)acrylate, 2,2,3,3,4,4,5,5,6,6,7,7-dodecafluoroheptyl (meth)acrylate, 2,2,3,3,4,4,4-heptafluorobutyl (meth)acrylate, 1H,1H,2H,2H-perflurorodecyl (meth)acrylate, trimethylolpropane ethoxylate tri-(meth)acrylate, poly(ethylene glycol) di(meth)acrylate, ethyl (meth)acrylate, 2(2-ethoxyethoxy)-ethyl (meth)acrylate, butyl (meth)acrylate, isodecyl (meth)acrylate, 1,6-hexanediol di(meth)acrylate, 2,2,3,3,4,4-hexafluoro-1,5-pentyl di(meth)acrylate, acrylonitrile, 1-cyanovinyl acetate, ethyl 2-cyanoacrylate, vinyl-terminated polydimethylsiloxanes, urethane acrylates, etc. Particular example compositions include DMS-V31 and DMS-V00 (Gelest, Inc.), Silmer VIN 65,000 and Silmer VIN 10,000 (Siltech Corporation), NAM-122P and NAM-UXF4001M35 (NAGASE America), and GN4230 and GN4122 (RAHN USA Corp.).

According to some embodiments, the polymer precursor may include a mixture of multi-functional vinyl containing species, as described above, and multi-functional thiol-containing species with an average functionality greater than 2. The thiol-containing species may include di-thiols, tri-thiols, tetra-thiols, thiol-terminated fluoro-(pre)polymers, thiol-terminated silicone-(pre)polymers, thiol-terminated polydimethylsiloxanes, thiol-terminated urethane-(pre)polymers, thiol-terminated ethylene glycol-(pre)polymers, thiol-terminated thiolether-(pre)polymers, and the like. Particular examples of thiol-containing reactive molecules include trimethylolpropane tris(3-mercaptopropionate), 2,2′-(ethylenedioxy) diethanethiol, pentaerythritol tetrakis(3-mercaptopropionate), 1,4-butanedithiol, tetra(ethylene glycol) dithiol, poly(ethylene glycol) dithiol, pentaerythritol tetrakis(3-mercapopropionate), thiol-terminated polydimethylsiloxane, and the like.

In some embodiments, the polymer precursor may include a mixture of hydrides (Si—H) and vinyl-containing siloxanes that may be heated with an organometallic catalyst, such as a platinum-based catalyst, to build a crosslinked polydimethylsiloxane elastomer. A silicon hydride may include, for example, 1,1,3,3,5,5,7,7-octamethyltetrasiloxane. An organometallic catalyst may include soluble platinum compounds such as chloroplatinic acid, dicyclopentadiene platinum(II) dichloride, or a platinum complex such as a platinum-divinyltetramethyldisiloxane complex.

In some embodiments, the polymer precursor may include a mixture of siloxanes, silane-containing crosslinkers and a titanium-based or tin-based catalyst. Silane-containing crosslinkers may include alkoxy, acetoxy, ester, epoxy and oxime silanes. Titanium-based catalysts may include titanates or organo-titanates, e.g., tetraalkoxy titanates, whereas tin-containing catalysts may include chelated tin or organo-tins, e.g., dibutyl tin dilaurate.

In some embodiments, the polymer precursor may include a mixture of multi-functional isocyanate-containing species and multi-functional proton donating species with an average functionality greater than 2. The isocyanate-containing species may include hexamethylene diisocyanate, isophorone diisocyanate, 1,4-diisocyanatobutane, toluene 2,4-diisocyanate, methylene diphenyl 4,4′-diisocyanate, methylidynetri-p-phenylene triisocyanate, tetraisocyanatosilane, etc., as well as various blocked isocyanates. Blocked isocyanates are the reaction products of isocyanates with, for example, phenols, caprolactam, oximes, or (3-di-carbonyl compounds, which at elevated temperatures disassociate to reform the original isocyanate group.

The proton donating species may include alcohols and polyols such as, for example, ethylene glycol, 1,4-butanediol, 1,6-hexanediol, p-di(2-hydroxyethoxy) benzene, polyethylene glycol, polycaprolactone diol, polypropylene glycol triol, polycaprolactone triol, and the like. In some examples, the proton donating species may include various thiols, as disclosed herein. According to further examples, the proton donating species may include amines, for example, diethyltoluenediamine, methylene bis(p-aminobenzene), 3,3′-dichloro-4,4′-diaminodiphenylmethane, etc.

Further example catalysts that may be incorporated into the polymerizable composition include tertiary amines, such as triethylene diamine, or N,N,N′,N′,N″-pentamethyl-diethylene-triamine, strong bases, such as 1,8-diazabicyclo[5.4.0]undec-7-ene, or 1,5-diazabicyclo[4.3.0]non-5-ene. Strong base catalysts may be protected and become active upon light irradiation.

Example solid and sublimable templating agents may include polycyclic aromatic hydrocarbons (e.g., 2-naphthol, anthracene, etc.), benzoic acid, salicylic acid, camphor, saccharin, quinine, cholesterol, palmitic and stearic acids, acetylsalicylic acid, atropine, arsenic, piperazine, 1,4-dichlorobenzene, as well as combinations thereof. In some aspects, a templating agent may be vaporizable and characterized by a sublimation temperature of greater than approximately 30° C. For instance, a templating agent may sublime at atmospheric pressure at a temperature of from approximately 30° C. to approximately 300° C., e.g., approximately 30° C., approximately 50° C., approximately 75° C., approximately 100° C., approximately 150° C., approximately 200° C., approximately 250° C., or approximately 300° C., including ranges between any of the foregoing values. The sublimation temperature may be decreased by decreasing the sublimation pressure, e.g., to a pressure less than atmospheric pressure.

In some embodiments, the solid templating agent may be sufficiently soluble in the polymer precursor to form a homogeneous mixture, i.e., a liquid solution. As used herein, in a “homogeneous solution,” the components that make up the solution are uniformly distributed on the molecular level, such that the composition of the solution is the same throughout. As will be appreciated, only a single phase is observed in a homogeneous solution.

According to some embodiments, in addition to the polymer precursor (curable material) and the solid templating agent, a polymerizable composition may include one or more additional components, such as a polymerization initiator, surfactant, emulsifier, catalyst and/or other additive(s) such as cross-linking agents. The various components of the polymerizable composition may be combined into a single batch and deposited simultaneously.

The polymerizable composition may be deposited onto any suitable substrate. In some embodiments, the substrate may be transparent or translucent. Example substrate materials may include glass and polymeric compositions, which may define various optical element architectures such as a lens. As disclosed herein, further example substrates may include transparent conductive layers, such as transparent conductive electrodes.

In certain embodiments, prior to depositing the polymerizable composition, a substrate surface may be pre-treated or conditioned, for example, to improve the wettability or adhesion of the deposited layer(s). Pretreatment of the substrate may include a subtractive or an additive process. For instance, substrate pre-treatments may include one or more of a plasma treatment (e.g., CF4 plasma), thermal treatment, e-beam exposure, UV exposure, UV-ozone exposure, mechanical abrasion, or coating (e.g., spin coating, dip coating, or electrospray coating) with a layer of solvent, nanoparticles, or a self-assembled monolayer. As will be appreciated, the formation of a self-assembled monolayer may be substrate dependent. Example of self-assembled monolayers may include one or more terminal groups, such as alkanethiols, —COOH, —NH₂, —OH, etc.

The substrate pre-treatment may increase or decrease the roughness of the substrate surface. The substrate pre-treatment may increase or decrease the surface energy of the substrate surface. In certain embodiments, a substrate pre-treatment may be used to affect nucleation and growth of the templating material into crystalline domains. In some embodiments, the pre-treatment may be used to form a hydrophilic surface or a hydrophobic surface. In some embodiments, the pre-treatment may be used to form a lipophilic surface or a lipophobic surface.

The substrate may include a photo alignment layer, e.g., a blanket or patterned layer that may be used to globally or locally promote nucleation and growth of a crystalline phase. Example photoalignment materials include azobenzene derivatives or cinnamate-moieties, such as Rolic® ROP 131-306 or Rolic® LCMO-VA. In some embodiments, the substrate may include an inorganic layer, e.g., SiOₓ, which may be an obliquely deposited layer. In some embodiments, the deposition surface of the substrate may include a layer of an organic material or an inorganic material, which may be obliquely etched, such as by an ion beam. In some embodiments, the substrate may include a semi-crystalline polymer.

As will be appreciated, conventional photolithography techniques may be used to spatially affect pretreatment of the substrate. For instance, a patterned and sacrificial layer of photoresist or a patterned and sacrificial hard mask may be used to locally obscure portions of the deposition surface during a pre-treatment step, e.g., in order to spatially discourage nucleation and growth of a crystalline phase within the obscured areas. That is, the deposition surface of the substrate may be modified to promote spatially localized deposition of both a polymer precursor and a templating agent.

In various embodiments, the polymerizable composition may be deposited at approximately atmospheric pressure, although the deposition pressure is not particularly limited and may be conducted at reduced pressure, e.g., from approximately 0.1 Torr to approximately 760 Torr, e.g., 0.1, 0.2, 0.5, 1, 2, 5, 10, 20, 50, 100, 200, 500, or, 760 Torr, including ranges between any of the foregoing values.

During one or more deposition steps, the substrate temperature may be maintained at approximately room temperature (ca. 23° C.), although lesser and greater substrate temperatures may be used. For instance, the substrate temperature may range from approximately −50° C. to approximately 250° C., e.g., −50° C., −40° C., −20° C., 0° C., 20° C., 40° C., 60° C., 80° C., 100° C., 120° C., 140° C., 160° C., 180° C., 200° C., or 250° C. including ranges between any of the foregoing values, and may be held substantially constant or varied during the deposition.

According to some embodiments, a thickness of a coating of the polymerizable composition may range from approximately 5 nm to approximately 3 millimeter, e.g., approximately 5 nm, approximately 10 nm, approximately 20 nm, approximately 50 nm, approximately 100 nm, approximately 200 nm, approximately 500 nm, approximately 1 μm, approximately 2 μm, approximately 5 μm, approximately 10 μm, approximately 20 μm, approximately 50 μm, approximately 100 μm, approximately 200 μm, approximately 500 μm, approximately 1 mm, approximately 2 mm, or approximately 3 mm including ranges between any of the foregoing values.

The deposited polymerizable composition may form a coating or thin film on the substrate, which may be cured to cross-link and polymerize the polymer precursor. A curing source such as a light source or a heat source, for example, may be used to process the polymerizable composition. In some embodiments, polymerization may be achieved by exposing the coating to actinic radiation. In some examples, “actinic radiation” may refer to energy capable of breaking covalent bonds in a material. Examples may include electrons, electron beams, neutrons, alpha particles (He²⁺), x-rays, gamma rays, ultraviolet and visible light, and ions, including plasma, at appropriately high energy levels. By way of example, a single UV lamp or a set of UV lamps may be used as a source for actinic radiation. When using a high lamp power, the curing time may be reduced. Other sources for actinic radiation may include a laser (e.g., a UV, IR, or visible laser) or a light emitting diode (LED).

Additionally or alternatively, a heat source may generate heat to initiate reaction between the polymer precursor, initiators, and/or cross-linking agents. The polymer precursor, initiators, and/or cross-linking agents may react upon heating and/or actinic radiation exposure to form a polymer as described herein.

In some embodiments, polymerization may be free radical initiated. In such embodiments, free radical initiation may be performed by exposure to actinic radiation or heat. In addition to, or in lieu of, actinic radiation and heat-generated free radicals, polymerization of the voided polymer may be atom transfer radical initiated, electrochemically initiated, plasma initiated, or ultrasonically initiated, as well as combinations of the foregoing. In certain embodiments, example additives to the polymerizable composition that may be used to induce free radical initiation include thermal initiators such as azo compounds, and peroxides, or photoinitiators such as phosphine oxide.

In some embodiments, the polymer precursor may be polymerized, e.g., without using a polymerization initiator, using short wavelength radiation, such as an electron beam, neutrons, alpha particles (He²⁺), gamma or x-ray radiation. According to further embodiments, the polymer precursor may be polymerized using UV or visible light in combination with a photoinitiator. Example UV radical initiators include 2-hydroxy-2-methylpropiophenone, 2-hydroxy-2-phenylacetophenone, 2-methylbenzophenone, phosphine oxide, diphenyl(2,4,6-trimethylbenzoyl) phosphine oxide, 3′-hydroxyacetophenone, benzophenone, and 1-hydroxycyclohexyl phenyl ketone blend. In the example of a polymer precursor containing a vinylether or a vinylether terminated-(pre)polymer, polymerization may be initiated using a UV cationic initiator, such as a triarylsulfonium hexafluoroantimonate salt, or bis(4-tert-butylphenyl)iodonium perfluoro-1-butanesulfonate. In some embodiments, polymerization may be initiated using a thermal radical initiator, such as 2,2′-azobisisobutyronitrile, benzoyl peroxide, tert-butyl peroxide, etc. In some embodiments, polymerization may be initiated using a redox radical initiator. Example redox radical initiators include peroxide-amine mixtures, such as a mixture of benzoyl peroxide and N,N-dimethylaniline.

In some embodiments, the polymerization process may not be limited to a single curing step. Rather, it may be possible to carry out polymerization by two or more steps, whereby, as an example, the coating of the polymerizable composition may be exposed to two or more lamps of the same type or two or more different lamps in sequence. The curing temperature of different curing steps may be the same or different. The lamp power, wavelength, and dose from different lamps may also be the same or different. In one embodiment, polymerization may be carried out in air; however, polymerizing in an inert gas atmosphere such as nitrogen or argon is also contemplated.

In various aspects, the curing time may depend on the reactivity of the coating, the thickness of the coating, the type of polymerization initiator and the power of a UV lamp. The UV curing time may be approximately 60 minutes or less, e.g., less than 5 minutes, less than 3 minutes, or less than 1 minute. In another embodiment, short curing times of less than 30 seconds may be used for mass production.

As will be appreciated, curing of the deposited layer may induce phase separation between the nascent polymer layer and the templating agent. Before or during the act of curing, the control of temperature and/or pressure may induce the dissolved template material to solidify, e.g., via precipitation and/or crystallization, to form discrete regions or domains of a solid phase. The templating material within such domains may be crystalline or amorphous. In some examples, the templating material may form dendritic grains having long-range order. The domain architecture may be patterned to have a desired shape and/or, in the example of crystalline domains, to exhibit a preferred crystallographic orientation. In some examples, patterned domains may have an anisotropic feature, such as a spatial dimension, that is oriented along a particular direction. Additionally or alternatively, a distance between patterned domains may be controlled such that plural domains may be configured randomly or in a regular or semi-regular array.

In a further processing step, the templating agent may be removed from the polymer matrix to form voids, i.e., in regions previously occupied by the templating material. In some embodiments, a change in temperature and/or pressure may be used to sublimate the templating agent.

Prior to the sublimation and attendant removal of the templating material from the polymer matrix, a capping layer may be formed over the polymer layer. In accordance with various embodiments, a substantially dense (substantially void-free) capping layer may be formed from a modified polymerizable composition using any of the deposition methods and materials disclosed herein. Thus, although a modified polymerizable composition may include a polymer precursor and other optional additive(s) (e.g., initiator, surfactant, emulsifier, catalyst, cross-linking agent, and the like) as in previous embodiments, a templating agent is omitted from the modified polymerizable composition. By depositing a non-porous capping layer, a nanovoided polymer layer may be provided with a substantially flat, void-free surface amenable to further processing, such as the formation of conductive electrodes.

A capping layer, if provided, may include the same polymer material(s) as the adjacent voided polymer matrix, of the composition of the capping layer and the polymer matrix may be different.

The voided polymer layers disclosed herein may be incorporated into various optical elements. According to certain embodiments, an optical element may include a primary electrode, a secondary electrode overlapping at least a portion of the primary electrode, and a voided polymer layer disposed between and abutting the primary electrode and the secondary electrode.

In some embodiments, an optical element may include a tunable lens and an electroded layer of a voided polymer disposed over a first surface of the tunable lens. The tunable lens may be a liquid lens, for example, and may have a geometry selected from prismatic, freeform, plano, meniscus, bi-convex, plano-convex, bi-concave, or plano-concave. In certain embodiments, a further optical element may be disposed over a second surface of the tunable lens. The optical element may be incorporated into a head mounted display, e.g., within a transparent aperture thereof.

In accordance with various embodiments, liquid lenses can be used to enhance imaging system flexibility across a wide variety of applications that benefit from rapid focusing. According to certain embodiments, by integrating an actuatable liquid lens, an imaging system can rapidly change the plane of focus to provide a sharper image, independent of an object's distance from the camera. The use of liquid lenses may be particularly advantageous for applications that involve focusing at multiple distances, where objects under inspection may have different sizes or may be located at varying distances from the lens, such as package sorting, barcode reading, security, and rapid automation, in addition to virtual reality/augmented reality devices.

In the presence of an electrostatic field (E-field), an electroactive polymer (i.e., a voided polymer) may deform (e.g., compress, elongate, bend, etc.) according to the magnitude and direction of the applied field. Generation of such a field may be accomplished by placing the electroactive polymer between two electrodes, e.g., a primary electrode and a secondary electrode, each of which is at a different potential. As the potential difference (i.e., voltage difference) between the electrodes is increased or decreased (e.g., from zero potential) the amount of deformation may also increase, principally along electric field lines. This deformation may achieve saturation when a certain electrostatic field strength has been reached. With no electrostatic field, the electroactive polymer may be in its relaxed state undergoing no induced deformation, or stated equivalently, no induced strain, either internal or external.

The electrodes (e.g., the primary electrode and the secondary electrode) may include one or more electrically conductive materials, such as a metal, a semiconductor (e.g., a doped semiconductor), carbon nanotubes, graphene, oxidized graphene, fluorinated graphene, hydrogenated graphene, other graphene derivatives, carbon black, transparent conductive oxides (TCOs, e.g., indium tin oxide (ITO), zinc oxide (ZnO), etc.), or other electrically conducting materials. In some embodiments, the electrodes may include a metal such as aluminum, gold, silver, platinum, palladium, nickel, tantalum, tin, copper, indium, gallium, zinc, alloys thereof, and the like. Further example transparent conductive oxides include, without limitation, aluminum-doped zinc oxide, fluorine-doped tin oxide, indium-doped cadmium oxide, indium zinc oxide, indium gallium tin oxide, indium gallium zinc oxide, indium gallium zinc tin oxide, strontium vanadate, strontium niobate, strontium molybdate, calcium molybdate, and indium zinc tin oxide.

In other embodiments, the electrodes may include one or more conducting polymers, such as poly(3,4-ethylenedioxythiophene) polystyrene sulfonate, poly(3,4-ethylenedioxythiophene), poly(3,4-ethylenedioxythiophene) complexed with ions including Na¹⁺, Li¹⁺, H¹⁺, NH₄¹⁺, K¹⁺, Mg²⁺, or other anionic or cationic counter cations, polyaniline, polyacetylene, polyphenylene vinylene, poly pyrrole, polythiophene; polyphenylene sulfide, or other conductive polymers.

In some embodiments, the electrodes (e.g., the primary electrode and the secondary electrode) may have a thickness of approximately 1 nm to approximately 1000 nm, with an example thickness of approximately 10 nm to approximately 50 nm. Some of the electrodes may be designed to allow healing of electrical breakdown (e.g., associated with the electric breakdown of elastomeric polymer materials). A thickness of an electrode that includes a self-healing material (e.g., aluminum) may be approximately 30 nm.

The electrodes may be configured to stretch elastically. In such embodiments, the electrodes may include TCO particles, graphene, carbon nanotubes, and the like. In other embodiments, relatively rigid electrodes (e.g. electrodes including a metal such as aluminum) may be used. An electrode, i.e., the electrode material, may be selected to achieve a desired conductivity, deformability, transparency, and optical clarity for a given application. By way of example, the yield point of a deformable electrode may occur at an engineering strain of at least 0.5%.

The electrodes (e.g., the primary electrode and the secondary electrode) may be fabricated using any suitable process. For example, the electrodes may be fabricated using physical vapor deposition (PVD), chemical vapor deposition (CVD), evaporation, spray-coating, dip-coating, spin-coating, atomic layer deposition (ALD), and the like. In another aspect, the electrodes may be manufactured using a thermal evaporator, a sputtering system, a spray coater, a spin coater, and the like.

The application of a voltage between the electrodes can cause compression of the intervening voided polymer layer(s) in the direction of the applied electric field and an associated expansion or contraction of the polymer layer(s) in one or more transverse dimensions as characterized by the Poisson's ratio for the material. In some embodiments, an applied voltage (e.g., to the primary electrode and/or the secondary electrode) may create at least approximately 0.01% strain (e.g., an amount of deformation in the direction of the applied force resulting from the applied voltage divided by the initial dimension of the material) in the voided polymer layer in at least one direction (e.g., an x, y, or z direction with respect to a defined coordinate system).

Actuatable voided polymer layers may be incorporated into a variety of passive and active optics. Example structures include tunable prisms and gratings as well as tunable form birefringent structures, which may include either a patterned voided polymer layer having a uniform porosity or an un-patterned voided polymer layer having spatially variable porosity. In some embodiments, the optical performance of a voided polymer grating may be tuned through actuation of the grating, which may modify the pitch or height of the grating elements. In some embodiments, a voided polymer layer having a tunable refractive index may be incorporated into an actively switchable optical waveguide. According to some embodiments, one or more optical properties of an optical element may be tuned through capacitive actuation, mechanical actuation, and/or acoustic actuation.

While the voided materials of the present disclosure are described generally in connection with passive and active optics, the voided materials may be used in other fields. For example, the voided polymers may be used as part of, or in combination with, optical retardation films, polarizers, compensators, beam splitters, reflective films, alignment layers, color filters, antistatic protection sheets, electromagnetic interference protection sheets, polarization-controlled lenses for autostereoscopic three-dimensional displays, infrared reflection films, and the like.

In accordance with some embodiments, a voided polymer layer may be formed using top-down or bottom-up deposition and patterning schemes. In a top-down process, a bulk voided polymer layer may be formed and subsequently patterned, e.g., using lithography and etch processes, to define a 2D or 3D optical element. In a bottom-up process, a 2D or 3D optical element may be formed layer-by-layer by selective deposition. In an example bottom-up process, the acts of curing and sublimation of the templating agent may be performed after the complete structure is deposited or following the deposition of each of a plurality of successive layers.

Features from any of the embodiments described herein may be used in combination with one another in accordance with the general principles described herein. These and other embodiments, features, and advantages will be more fully understood upon reading the following detailed description in conjunction with the accompanying drawings and claims.

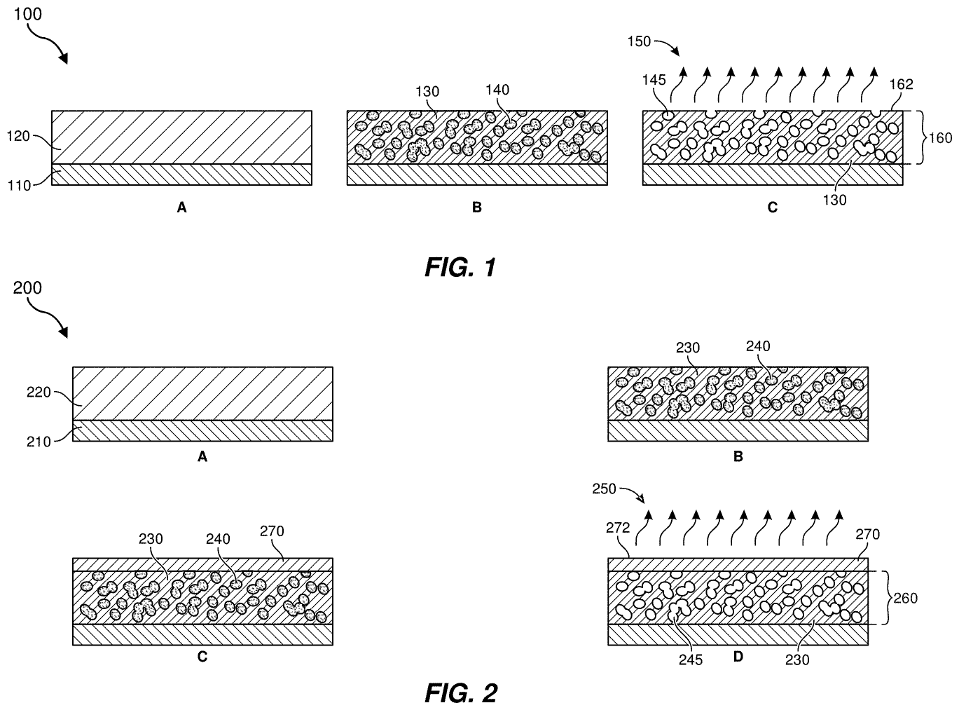

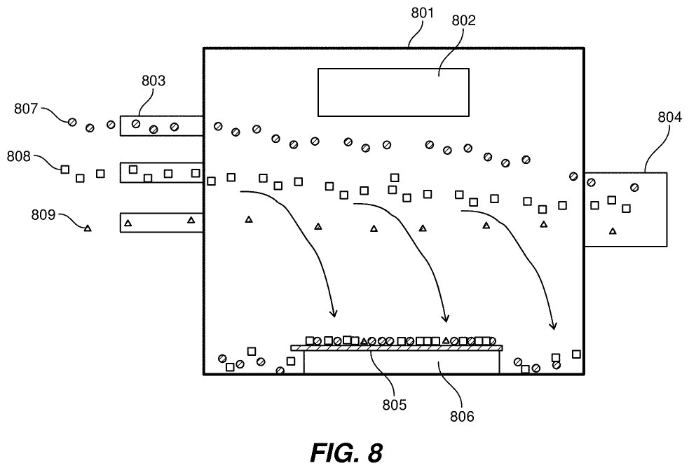

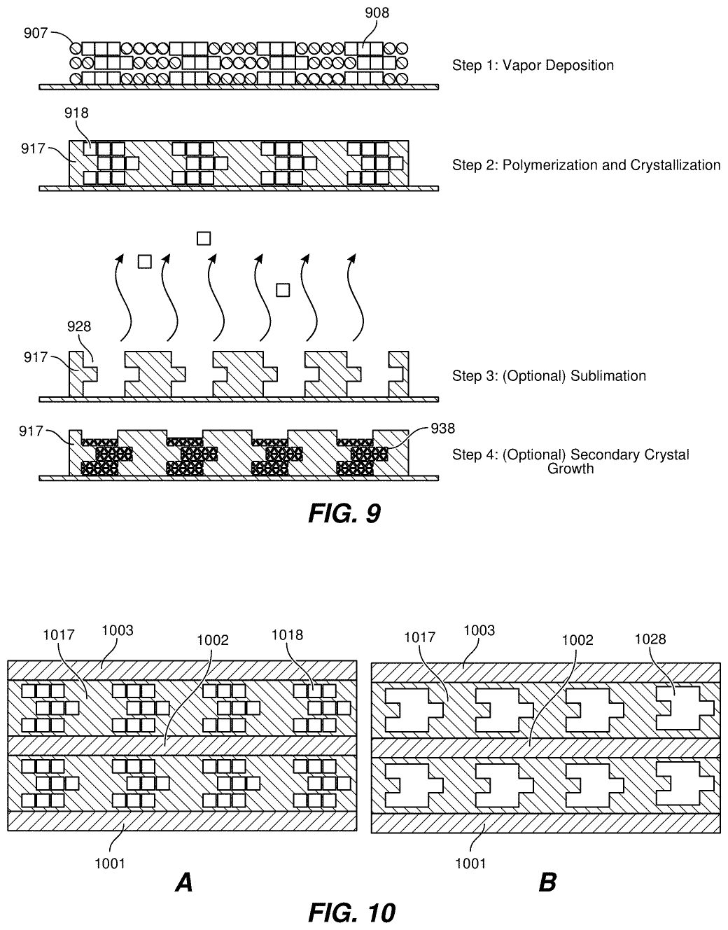

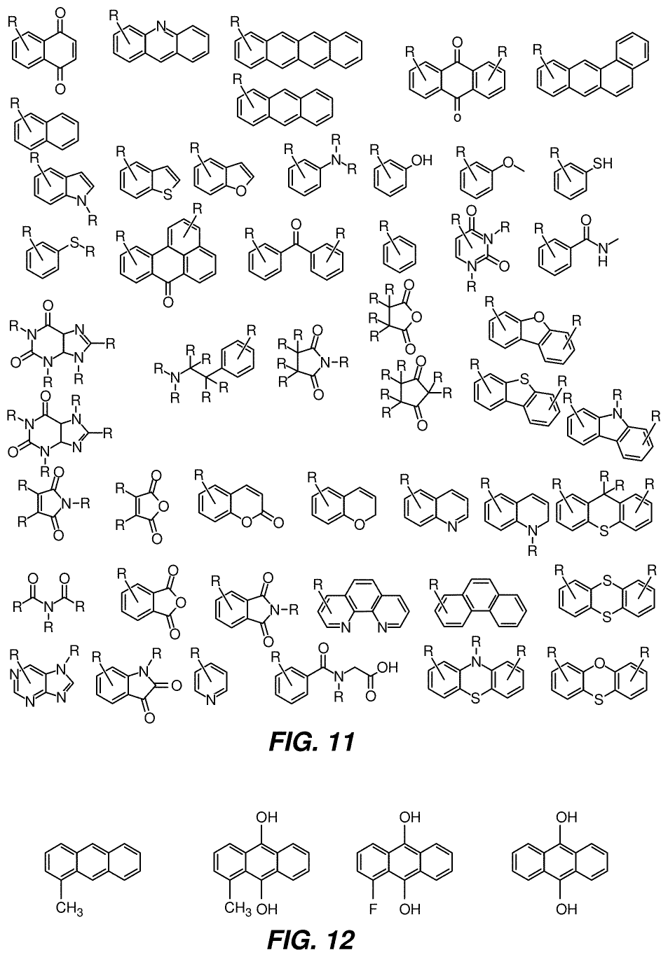

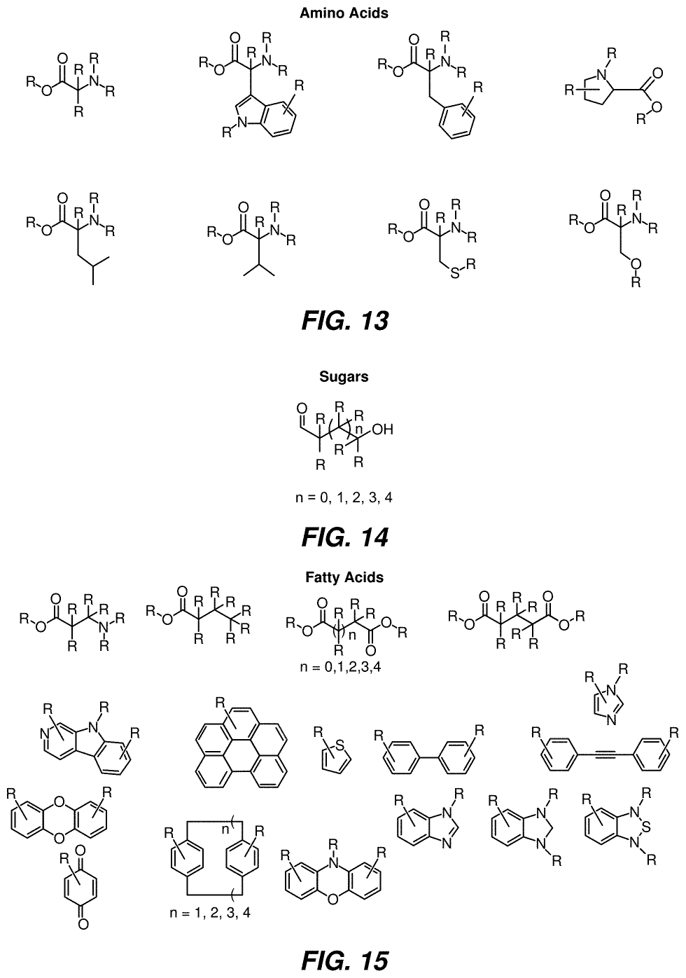

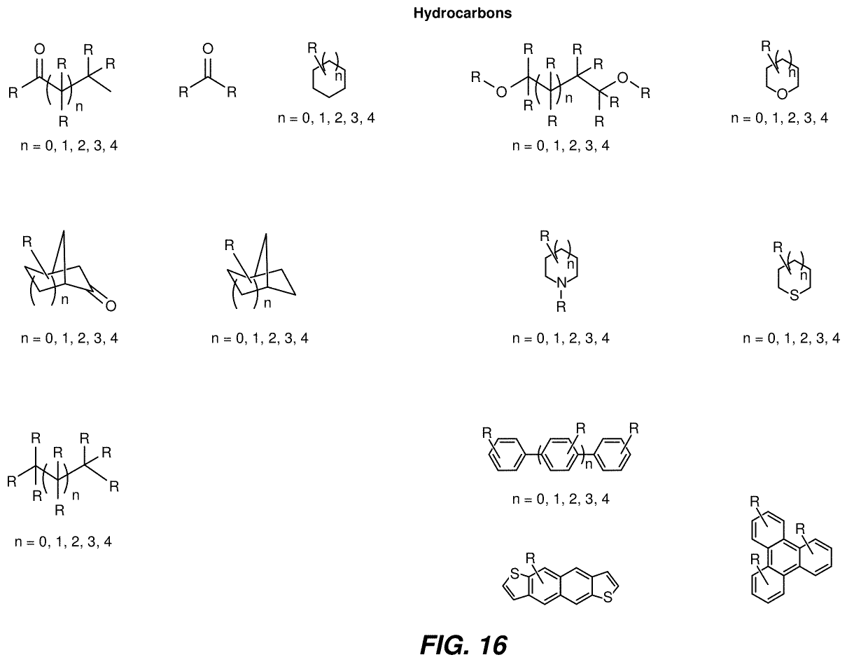

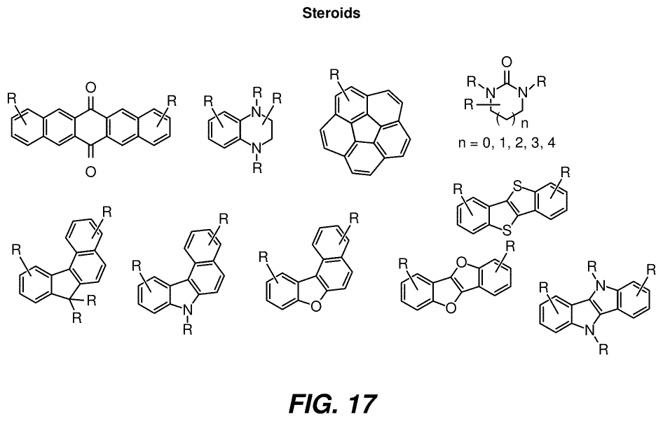

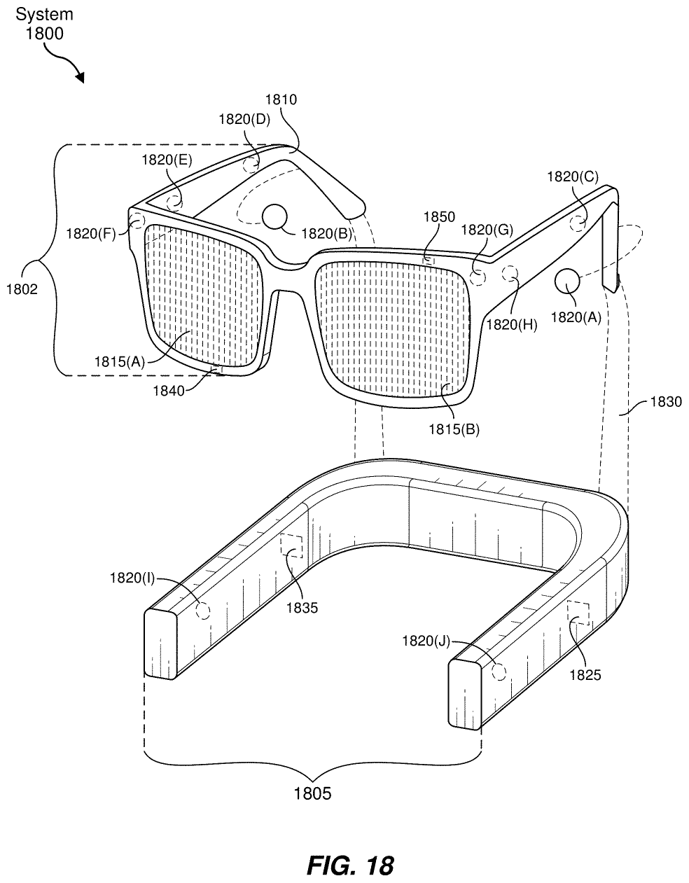

The following will provide, with reference to FIGS. 1-22, detailed descriptions of voided polymer materials, including methods of manufacturing voided polymers using a polymerizable composition that includes a solid tem plating agent. The discussion associated with FIGS. 1-5 includes a description of example sublimation methods of forming nanovoided polymers and nanovoided polymer-containing architectures. The discussion associated with FIGS. 6 and 7 includes a description of the void structure in example voided polymer layers. The discussion associated with FIGS. 8 and 9 includes a description of a vapor deposition process for forming composite or nanovoided polymer materials. The discussion associated with FIG. 10 illustrates example composite architectures that include composite or nanovoided polymer materials. FIGS. 11-17 show example vaporizable and crystallizable materials that may be used in a vapor deposition process to form such materials. The discussion associated with FIGS. 18-22 relates to exemplary virtual reality and augmented reality devices that may include an optical element having a nanovoided polymer layer.

Shown schematically in FIG. 1 is an example method for forming a voided polymer. Referring initially to FIG. 1A, method 100 may include forming a coating 120 of a polymerizable composition on a substrate 110. Coating 120 may include a homogeneous solution of a polymer precursor and a solid templating agent. In a subsequent curing step, as illustrated in FIG. 1B, the coating 120 may be cross-linked and polymerized to form a polymer matrix 130 including a plurality of solid template-containing domains 140 dispersed throughout the polymer matrix 130. Referring to FIG. 1C, at least a portion of the template material within domains 140 may be removed, e.g., by sublimation 150, to form a voided polymer layer 160 including a plurality of voids 145 distributed throughout the polymer matrix 130. As shown schematically in FIG. 1, voids 145 may be exposed at a surface 162 of polymer layer 160.

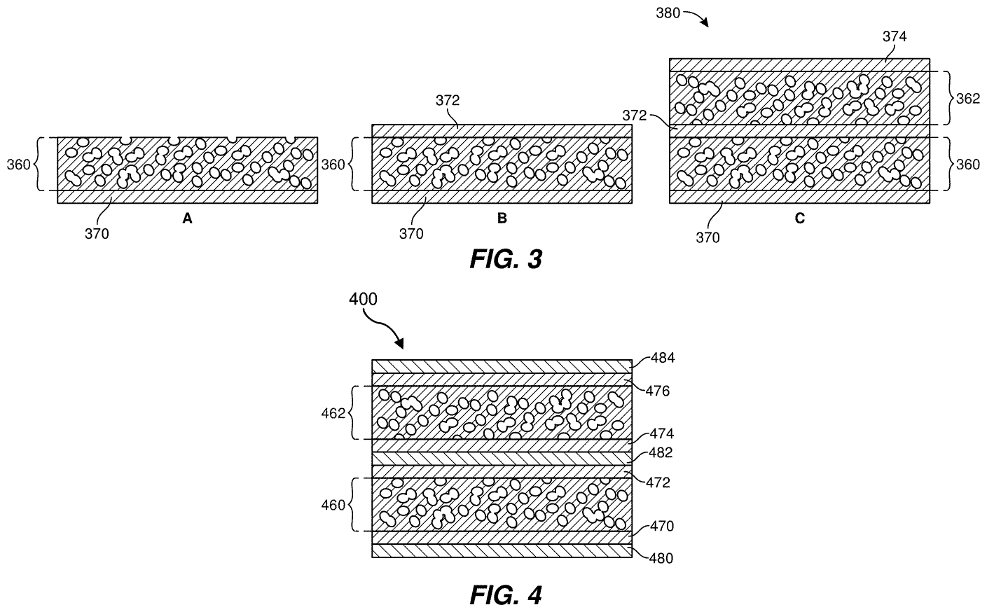

According to some embodiments, a capping layer may be formed over a surface of a nanovoided polymer layer to provide a smooth surface, uninterrupted by exposed voids. Referring to FIG. 2, method 200 may include forming a coating 220 of a polymerizable composition on a substrate 210, as shown in FIG. 2A. As in the previous embodiment, referring to FIG. 2B, the coating 220 may be cross-linked and polymerized to form a polymer matrix 230 including a plurality of solid template-containing domains 240 dispersed throughout the polymer matrix 230.

Prior to removal of the solid templating agent, a capping layer 270 may be formed over polymer matrix 230 from a modified polymerizable composition, as illustrated in FIG. 2C. The modified polymerizable composition may include a polymer precursor and other optional additives. However, a solid templating agent is omitted from the modified polymerizable composition.

Referring to FIG. 2D, at least a portion of the template material within domains 240 may be removed, e.g., by sublimation 250, to form a voided polymer layer 260 including a plurality of voids 245 distributed throughout the polymer matrix 230 and an overlying capping layer 270 having an un-voided surface 272. As will be appreciated, the foregoing methodology may be repeated to form multilayer architectures including one or more voided polymer layer and one or more capping layers.

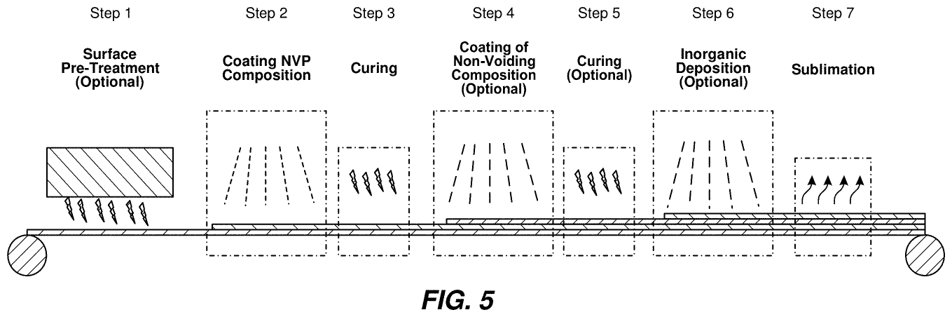

Referring to FIG. 3, illustrated are example multilayer structures that include one or more voided polymer layers. As shown in FIG. 3A, a voided polymer layer 360 may be disposed over a capping layer 370. Referring to FIG. 3B, a voided polymer layer 360 may be disposed between a first capping layer 370 and a second capping layer 372. A stacked structure 380 is illustrated in FIG. 3C. Stacked structure 380 may include, from bottom to top, a first capping layer 370, a first voided polymer layer 360, a second capping layer 372, a second voided polymer layer 362, and a third capping layer 374.

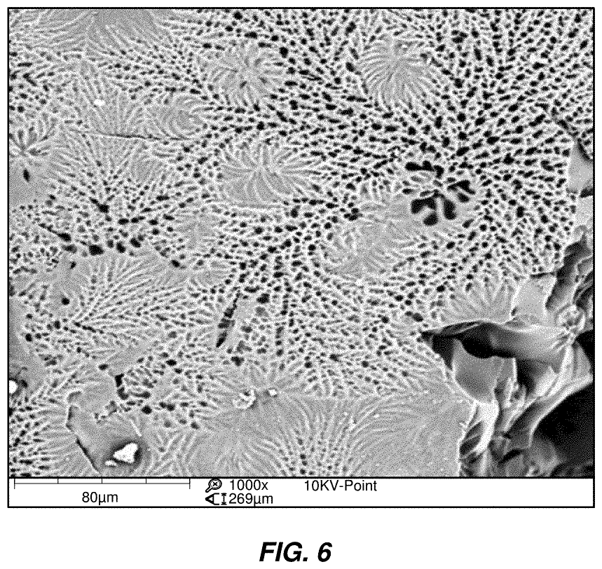

In some embodiments, a voided polymer layer may be integrated with one or more conductive electrodes. By way of example, an electroded, multilayer stack 400 is illustrated in FIG. 4 and includes, from bottom to top, a primary electrode 480, a first capping layer 470, a first voided polymer layer 460, a second capping layer 472, a secondary electrode 482, a third capping layer 474, a second voided polymer layer 462, a fourth capping layer 476, and a tertiary electrode 484.

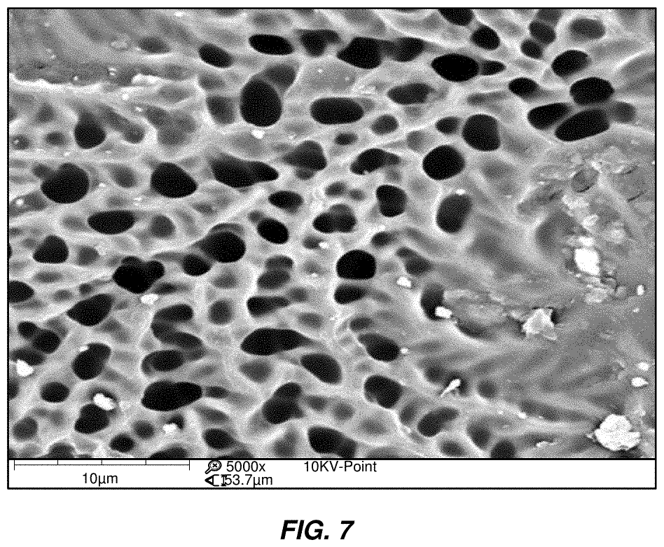

Further to the foregoing, as shown schematically in FIG. 5, an example manufacturing process may include the acts of substrate pre-treatment (step 1), deposition onto the substrate of a polymerizable composition to form a deposited layer including a polymer precursor and a solid templating agent (step 2), curing to form a polymer layer (step 3), deposition over the polymer layer of a modified polymerizable composition (step 4), curing to form a dense capping layer over the polymer layer (step 5), electrode formation (step 6), and sublimation (step 7) to remove the solid templating agent from the polymer layer to form a capped and electroded voided polymer layer. As will be appreciated, a multilayer structure may be formed by repeating one or more of steps 2-6.

Scanning electron microscope (SEM) micrographs of example voided polymer materials are shown in FIG. 6 and FIG. 7. As seen in the micrographs, the voided polymer material includes a polymer matrix and a plurality of voids dispersed throughout the matrix. As will be appreciated, the voids exhibit long-range order and are non-homogeneously distributed throughout the polymer matrix.

An exemplary chemical vapor deposition (CVD) method for forming composite or voided polymer materials is shown schematically in FIG. 8. In the method of FIG. 8, a vacuum chamber 801 includes a radiation source 802 configured to initiate polymerization of a polymerizable composition that is introduced into the chamber 801. Radiation source 802 may include a hot filament or a filament array, or a radiation source such as a plasma, UV, x-rays, gamma rays, electrons or an electron beam, visible light, and ions at appropriate energy levels. Vacuum chamber 801 may include one or more inlets 803 and one or more outlets 804 for delivering and removing a polymerizable composition and biproducts thereof into and out of the chamber.

Within chamber 801, a substrate 805 may be disposed on a thermally controlled plate 806, which may be configured to heat or cool the substrate 805 to a desired temperature. Moreover, in accordance with various embodiments, one or more of the substrate temperature, the chamber temperature, and the pressure within the chamber may be held constant or varied throughout the deposition process.

In an example method, a polymer precursor 807, a templating agent 808, and an optional polymerization initiator 809 are introduced to the chamber 801 in the vapor state via the one or more inlets 803. As the foregoing reactants condense and deposit on the substrate 805, a composite thin film is formed on the deposition surface of the substrate via polymerization of the polymer precursor 807 and crystallization of the templating agent 808. In some embodiments, polymerization of the polymer precursor 807 may initiate in the gas phase, during, and/or subsequent to deposition. Un-condensed/un-reacted vapor may exit the chamber 801 via outlet 804.

In an epitaxial deposition process, for instance, chemical reactants are controlled, and the system parameters are set so that the depositing species 807-809 alight on the deposition surface of the substrate 805 and remain sufficiently mobile via surface diffusion to orient themselves according to the crystalline orientation or surface structure of the deposition surface.

An example process is shown schematically in FIG. 9. In Step 1, a thin film is formed via vapor deposition of a polymer precursor 907 and a templating agent 908 that condense on the substrate surface and segregate into discrete domains. In Step 2, polymer regions 917 and crystalline regions 918 are formed from polymerization and crystallization of the polymer precursor 907 and the templating agent 908, respectively, to form a composite thin film. Polymerization of the polymer precursor 907 and crystallization of the templating agent 908 may occur sequentially or simultaneously. During Step 1 and Step 2, one or more of flow rate, temperature, and pressure may be controlled to influence, for example, the crystallite size, order, and orientation of the crystalline regions 918. The crystallite size, order, and orientation of the crystalline regions 918 may also be influenced by the choice of the polymer precursor 907 and the templating agent 908, including composition, polarity, hydrophilicity, chirality, etc.

In addition to, or in lieu, of a polymerization initiator 809 or other catalyst, polymerization of the polymer precursor 907 may be advanced thermally or be advanced by radiation, such as by exposure of the nascent thin film to plasma, UV, x-rays, gamma rays, neutrons, alpha particles (He²⁺), visible light, an electron beam, etc.). In some cases, the polymerization may occur during the deposition process. In some cases, the polymerization occur may after the deposition is completed.

Referring still to FIG. 9, as shown in Step 3, a voided polymer thin film may be formed via sublimation of crystalline regions 918. In some embodiments, the resulting voids 928 may be backfilled, such as with a secondary crystalline material 938, as shown in Step 4.

According to some embodiments, stacked polymer architectures are shown schematically in FIG. 10. Referring to FIG. 10A and FIG. 10B, respectively, example multilayer structures may include composite polymer thin films and voided polymer thin films alternately disposed between layered substrates. Substrates 1001, 1002, and 1003 may include any suitable substrate as disclosed herein. In particular embodiments, substrates 1001, 1002, and 1003 may include cured layers of polymer precursor 907, i.e., single domain layers formed without a templating agent 808, 908.

Further example templating agents are shown in FIGS. 11-17. The illustrated materials may be used as enantiomerically pure compositions or as racemic mixtures and may be used alone or in any combination. In the illustrated structures, “R” may include any suitable functional group, including but not limited to, CH₃, H, OH, OMe, OEt, OiPr, F, Cl, Br, I, Ph, NO₂, SO₃, SO₂Me, i-Pr, Pr, t-Bu, sec-Bu, Et, acetyl, SH, SMe, carboxyl, aldehyde, amide, amine, nitrile, ester, SO₂NH₃, NH₂, NMe₂, NMeH, and C₂H₂, and “n” may be any integral value from 0 to 4 inclusive. The materials illustrated in FIGS. 11-17 may be characterized as vaporizable, crystallizable and, in some embodiments, sublimable.

Various example templating agents are shown in FIG. 11. Particular example templating agent compositions showing the addition of methyl-, hydroxyl-, and fluoro-functional groups to anthracene are shown in FIG. 12. Example amino acids are shown in FIG. 13, example sugars are shown in FIG. 14, and example fatty acids are shown in FIG. 15. As further examples, suitable hydrocarbons are shown in FIG. 16 and suitable steroid compositions are shown in FIG. 17.

In accordance with various embodiments, an illustrative synthesis route for forming a nanovoided polymer by template sublimation is set forth in Trial 1.

Trial 1—A solution was prepared by combining 2-phenyoxylethyl acrylate (SR339 from Sartomer, 40.75 wt. %), iso-decyl acrylate (SR395 from Sartomer, 40.75 wt. %), polyethylene glycol acrylate (CD553 from Sartomer, 10 wt. %), [3-prop-2-enoyloxy-2,2-bis(prop-2-enoyloxymethyl)propyl] propanoate (SR351 from Sartomer, 8 wt. %) and benzoin (0.5 wt. %). A mixture was then prepared by adding camphor (5.809 g) to the solution (5.608 g). The mixture was stirred and heated at 60° C. until the benzoin and the camphor were fully dissolved forming a homogeneous solution. The solution was encapsulated between two 8×50 mm glass slides with a 0.5 mm plastic spacer and heated to 60° C. The thin film was exposed to 365 nm UV radiation to polymerize the polymer precursors and form a polymer film. Camphor was removed via sublimation by heating the polymer film in an oven at 60° C. A total weight loss of approximately 50 wt. % was observed after 21 hours of heating. Scanning electron microscope imaging confirmed the formation of a dendritic network of voids having a diameter ranging from approximately 1 to 20 micrometers.

As disclosed herein, a nanovoided polymer may be formed from a polymerizable composition that includes a polymer precursor and a solid templating agent. Phase separation and sublimation of the templating material during or subsequent to curing of the polymer precursor may create a network of voids within regions of the nascent polymer matrix previously occupied by the template. Example templating materials include polycyclic aromatic hydrocarbons (such as 2-naphthol and anthracene), camphor, benzoic acid, and the like, although further solid materials are contemplated. In accordance with various embodiments, use of a solid, sublimable templating agent obviates complications associated with liquid templating agents, including absorption by the polymer matrix and surface tension-driven void collapse during extraction.

Curing may be accomplished by exposure to heat or actinic radiation, which may also promote phase separation between the templating material and the polymer precursor. Crystallization of the templating agent, which may occur prior to or during the act of curing, may lead to the formation of a network of voids having random, short-range, or long-range order within the polymer matrix. In some examples, the void structure may exhibit dendritic patterns. Sublimation may be advanced by one or more of a change in temperature, pressure, etc.

A variety of deposition techniques may be used to deposit a layer of the polymerizable composition onto a substrate. The chemistry of the polymerizable composition and the particulars of the deposition method may be used to tailor characteristics of the nanovoided polymer layer, including void size, void size distribution, void density, the extent of void short-order or void long-range order, etc., and correspondingly control its mechanical and optical properties, including actuation response, transmissivity, and birefringence.

In some embodiments, the average void size may range from approximately 5 nm to approximately 20 μm. In some embodiments, a void-free capping layer may be formed over a layer of the polymerizable composition prior to sublimation to create a nanovoided polymer layer having a planar, substantially pock-free surface.

Multilayer structures may include one or more nanovoided polymer layers, optionally including one or more capping layers, and may further include paired electrodes configured to capacitively actuate the nanovoided polymer layer(s). Such nanovoided polymer layers may be incorporated into passive or active optics using a top down method that includes patterning and etching a blanket voided polymer layer or using a bottom up method where a structured 2D or 3D element may be formed layer-by-layer.

### Example Embodiments

Example 1: A method includes forming a polymerizable composition that includes a polymer precursor and a solid templating agent, forming a coating of the polymerizable composition, processing the coating to form a cured polymer material that has a solid phase in a plurality of defined regions, and removing at least a portion of the solid phase from the cured polymer material to form a voided polymer layer.

Example 2: The method of Example 1, further including processing the polymerizable composition to form a homogeneous solution.

Example 3: The method of any of Examples 1 and 2, wherein removing at least a portion of the solid phase includes subliming the templating agent at a temperature between approximately 30° C. and approximately 300° C.

Example 4: The method of any of Examples 1-3, where the templating agent includes a polyaromatic hydrocarbon.

Example 5: The method of any of Examples 1-4, where the templating agent is selected from 2-naphthol, anthracene, benzoic acid, salicylic acid, camphor, saccharin, quinine, cholesterol, palmitic acid, stearic acid, acetylsalicylic acid, atropine, arsenic, piperazine, and 1,4-dichlorobenzene.

Example 6: The method of any of Examples 1-5, where the plurality of defined regions include templating material-rich domains having a maximum dimension of less than approximately 20 micrometers.

Example 7: The method of any of Examples 1-6, where removing at least a portion of the solid phase includes sublimation.

Example 8: The method of any of Examples 1-7, where the voided polymer layer has an elastic modulus of from approximately 0.2 MPa to approximately 500 MPa.

Example 9: The method of any of Examples 1-8, where the polymerizable composition further includes an initiator selected from a UV radical initiator, a thermal radical initiator, and a redox radical initiator.

Example 10: A method includes forming a homogeneous solution including a polymer precursor and a solid templating agent, forming a layer of the solution on a substrate, processing the layer to form a cured polymer material comprising discrete domains of a solid phase, and removing at least a portion of the solid phase from the domains to form a voided polymer layer.

Example 11: The method of Example 10, where the tem plating agent includes a polyaromatic hydrocarbon.

Example 12: The method of any of Examples 10 and 11, where the templating agent is selected from 2-naphthol, anthracene, benzoic acid, salicylic acid, camphor, saccharin, quinine, cholesterol, palmitic acid, stearic acid, acetylsalicylic acid, atropine, arsenic, piperazine, and 1,4-dichlorobenzene.

Example 13: The method of any of Examples 10-12, where removing at least a portion of the solid phase includes sublimation.

Example 14: A voided polymer including a polymer matrix having a plurality of voids non-homogeneously dispersed throughout the polymer matrix.

Example 15: The voided polymer of Example 14, where the voids exhibit a dendritic pattern.

Example 16: An actuator element including a layer of the voided polymer of any of Examples 14 and 15, where the voided polymer layer is disposed between conductive electrodes.

Example 17: An acoustic element including the voided polymer of any of Examples 14 and 15.

Example 18: A method includes introducing a vaporized reactant composition into a reaction chamber, the vaporized reactant composition including a polymer precursor and an organic templating agent, forming a coating comprising the reactant composition over a substrate located within the reaction chamber, and processing the coating to cure the polymer precursor and crystallize the organic templating agent to form a composite layer.

Example 19: The method of Example 18, further including removing at least a portion of the crystallized organic templating agent from the coating to form a voided polymer layer.

Example 20: The method of any of Examples 18 and 19, further including forming a polymer layer over a surface of the composite layer.

Example 21: The method of any of Examples 18-20, further including pretreating substrate to locally promote crystallization of the organic templating agent.

Example 22: The method of any of Examples 18-21, further including forming a photoalignment layer over the substrate prior to forming the coating.

Example 23: A composite structure including organic crystalline domains dispersed among polymer domains.

Example 24: The composite structure of Example 23, where the crystalline domains are characterized by a preferred crystallographic orientation.

Example 25: The composite structure of any of Examples 23 and 24, where the polymer domains are characterized by a glassy state.

Example 26: The composite structure of any of Examples 23-25, where the polymer domains are mechanically elastic.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

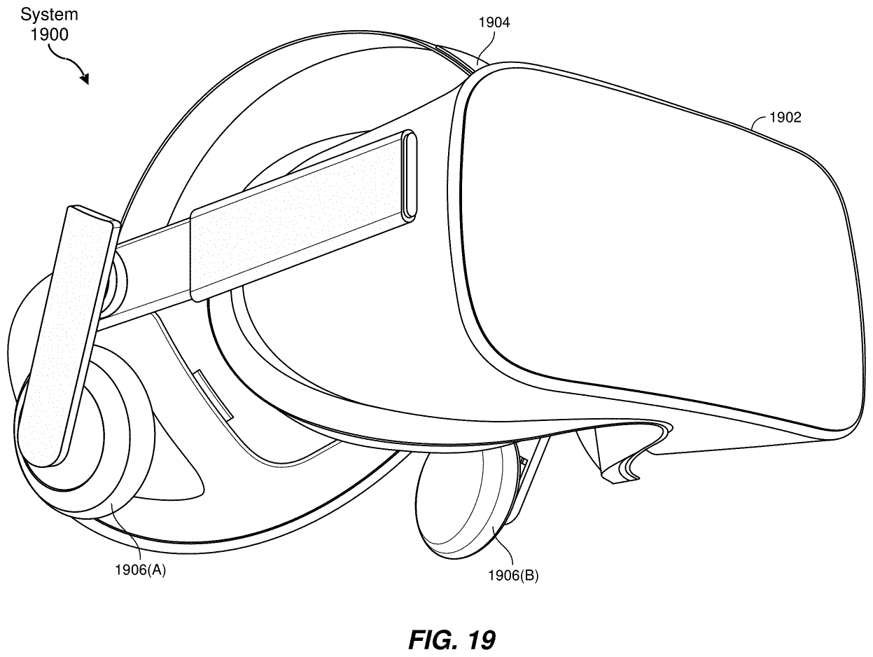

Artificial-reality systems may be implemented in a variety of different form factors and configurations. Some artificial-reality systems may be designed to work without near-eye displays (NEDs). Other artificial-reality systems may include an NED that also provides visibility into the real world (e.g., augmented-reality system 1800 in FIG. 18) or that visually immerses a user in an artificial reality (e.g., virtual-reality system 1900 in FIG. 19). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 18, augmented-reality system 1800 may include an eyewear device 1802 with a frame 1810 configured to hold a left display device 1815(A) and a right display device 1815(B) in front of a user's eyes. Display devices 1815(A) and 1815(B) may act together or independently to present an image or series of images to a user. While augmented-reality system 1800 includes two displays, embodiments of this disclosure may be implemented in augmented-reality systems with a single NED or more than two NEDs.

In some embodiments, augmented-reality system 1800 may include one or more sensors, such as sensor 1840. Sensor 1840 may generate measurement signals in response to motion of augmented-reality system 1800 and may be located on substantially any portion of frame 1810. Sensor 1840 may represent a position sensor, an inertial measurement unit (IMU), a depth camera assembly, a structured light emitter and/or detector, or any combination thereof. In some embodiments, augmented-reality system 1800 may or may not include sensor 1840 or may include more than one sensor. In embodiments in which sensor 1840 includes an IMU, the IMU may generate calibration data based on measurement signals from sensor 1840. Examples of sensor 1840 may include, without limitation, accelerometers, gyroscopes, magnetometers, other suitable types of sensors that detect motion, sensors used for error correction of the IMU, or some combination thereof.

Augmented-reality system 1800 may also include a microphone array with a plurality of acoustic transducers 1820(A)-1820(J), referred to collectively as acoustic transducers 1820. Acoustic transducers 1820 may be transducers that detect air pressure variations induced by sound waves. Each acoustic transducer 1820 may be configured to detect sound and convert the detected sound into an electronic format (e.g., an analog or digital format). The microphone array in FIG. 18 may include, for example, ten acoustic transducers: 1820(A) and 1820(B), which may be designed to be placed inside a corresponding ear of the user, acoustic transducers 1820(C), 1820(D), 1820(E), 1820(F), 1820(G), and 1820(H), which may be positioned at various locations on frame 1810, and/or acoustic transducers 1820(1) and 1820(J), which may be positioned on a corresponding neckband 1805.

In some embodiments, one or more of acoustic transducers 1820(A)-(F) may be used as output transducers (e.g., speakers). For example, acoustic transducers 1820(A) and/or 1820(B) may be earbuds or any other suitable type of headphone or speaker.

The configuration of acoustic transducers 1820 of the microphone array may vary. While augmented-reality system 1800 is shown in FIG. 18 as having ten acoustic transducers 1820, the number of acoustic transducers 1820 may be greater or less than ten. In some embodiments, using higher numbers of acoustic transducers 1820 may increase the amount of audio information collected and/or the sensitivity and accuracy of the audio information. In contrast, using a lower number of acoustic transducers 1820 may decrease the computing power required by an associated controller 1850 to process the collected audio information. In addition, the position of each acoustic transducer 1820 of the microphone array may vary. For example, the position of an acoustic transducer 1820 may include a defined position on the user, a defined coordinate on frame 1810, an orientation associated with each acoustic transducer 1820, or some combination thereof.

Acoustic transducers 1820(A) and 1820(B) may be positioned on different parts of the user's ear, such as behind the pinna, behind the tragus, and/or within the auricle or fossa. Or, there may be additional acoustic transducers 1820 on or surrounding the ear in addition to acoustic transducers 1820 inside the ear canal. Having an acoustic transducer 1820 positioned next to an ear canal of a user may enable the microphone array to collect information on how sounds arrive at the ear canal. By positioning at least two of acoustic transducers 1820 on either side of a user's head (e.g., as binaural microphones), augmented-reality device 1800 may simulate binaural hearing and capture a 3D stereo sound field around about a user's head. In some embodiments, acoustic transducers 1820(A) and 1820(B) may be connected to augmented-reality system 1800 via a wired connection 1830, and in other embodiments acoustic transducers 1820(A) and 1820(B) may be connected to augmented-reality system 1800 via a wireless connection (e.g., a Bluetooth connection). In still other embodiments, acoustic transducers 1820(A) and 1820(B) may not be used at all in conjunction with augmented-reality system 1800.

Acoustic transducers 1820 on frame 1810 may be positioned along the length of the temples, across the bridge, above or below display devices 1815(A) and 1815(B), or some combination thereof. Acoustic transducers 1820 may be oriented such that the microphone array is able to detect sounds in a wide range of directions surrounding the user wearing the augmented-reality system 1800. In some embodiments, an optimization process may be performed during manufacturing of augmented-reality system 1800 to determine relative positioning of each acoustic transducer 1820 in the microphone array.

In some examples, augmented-reality system 1800 may include or be connected to an external device (e.g., a paired device), such as neckband 1805. Neckband 1805 generally represents any type or form of paired device. Thus, the following discussion of neckband 1805 may also apply to various other paired devices, such as charging cases, smart watches, smart phones, wrist bands, other wearable devices, hand-held controllers, tablet computers, laptop computers, other external compute devices, etc.

As shown, neckband 1805 may be coupled to eyewear device 1802 via one or more connectors. The connectors may be wired or wireless and may include electrical and/or non-electrical (e.g., structural) components. In some cases, eyewear device 1802 and neckband 1805 may operate independently without any wired or wireless connection between them. While FIG. 18 illustrates the components of eyewear device 1802 and neckband 1805 in example locations on eyewear device 1802 and neckband 1805, the components may be located elsewhere and/or distributed differently on eyewear device 1802 and/or neckband 1805. In some embodiments, the components of eyewear device 1802 and neckband 1805 may be located on one or more additional peripheral devices paired with eyewear device 1802, neckband 1805, or some combination thereof.

Pairing external devices, such as neckband 1805, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 1800 may be provided by a paired device or shared between a paired device and an eyewear device, thus reducing the weight, heat profile, and form factor of the eyewear device overall while still retaining desired functionality. For example, neckband 1805 may allow components that would otherwise be included on an eyewear device to be included in neckband 1805 since users may tolerate a heavier weight load on their shoulders than they would tolerate on their heads. Neckband 1805 may also have a larger surface area over which to diffuse and disperse heat to the ambient environment. Thus, neckband 1805 may allow for greater battery and computation capacity than might otherwise have been possible on a stand-alone eyewear device. Since weight carried in neckband 1805 may be less invasive to a user than weight carried in eyewear device 1802, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 1805 may be communicatively coupled with eyewear device 1802 and/or to other devices. These other devices may provide certain functions (e.g., tracking, localizing, depth mapping, processing, storage, etc.) to augmented-reality system 1800. In the embodiment of FIG. 18, neckband 1805 may include two acoustic transducers (e.g., 1820(1) and 1820(J)) that are part of the microphone array (or potentially form their own microphone subarray). Neckband 1805 may also include a controller 1825 and a power source 1835.

Acoustic transducers 1820(1) and 1820(J) of neckband 1805 may be configured to detect sound and convert the detected sound into an electronic format (analog or digital). In the embodiment of FIG. 18, acoustic transducers 1820(1) and 1820(J) may be positioned on neckband 1805, thereby increasing the distance between the neckband acoustic transducers 1820(1) and 1820(J) and other acoustic transducers 1820 positioned on eyewear device 1802. In some cases, increasing the distance between acoustic transducers 1820 of the microphone array may improve the accuracy of beamforming performed via the microphone array. For example, if a sound is detected by acoustic transducers 1820(C) and 1820(D) and the distance between acoustic transducers 1820(C) and 1820(D) is greater than, e.g., the distance between acoustic transducers 1820(D) and 1820(E), the determined source location of the detected sound may be more accurate than if the sound had been detected by acoustic transducers 1820(D) and 1820(E).

Controller 1825 of neckband 1805 may process information generated by the sensors on neckband 1805 and/or augmented-reality system 1800. For example, controller 1825 may process information from the microphone array that describes sounds detected by the microphone array. For each detected sound, controller 1825 may perform a direction-of-arrival (DOA) estimation to estimate a direction from which the detected sound arrived at the microphone array. As the microphone array detects sounds, controller 1825 may populate an audio data set with the information. In embodiments in which augmented-reality system 1800 includes an inertial measurement unit, controller 1825 may compute all inertial and spatial calculations from the IMU located on eyewear device 1802. A connector may convey information between augmented-reality system 1800 and neckband 1805 and between augmented-reality system 1800 and controller 1825. The information may be in the form of optical data, electrical data, wireless data, or any other transmittable data form. Moving the processing of information generated by augmented-reality system 1800 to neckband 1805 may reduce weight and heat in eyewear device 1802, making it more comfortable to the user.

Power source 1835 in neckband 1805 may provide power to eyewear device 1802 and/or to neckband 1805. Power source 1835 may include, without limitation, lithium ion batteries, lithium-polymer batteries, primary lithium batteries, alkaline batteries, or any other form of power storage. In some cases, power source 1835 may be a wired power source. Including power source 1835 on neckband 1805 instead of on eyewear device 1802 may help better distribute the weight and heat generated by power source 1835.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 1900 in FIG. 19, that mostly or completely covers a user's field of view. Virtual-reality system 1900 may include a front rigid body 1902 and a band 1904 shaped to fit around a user's head. Virtual-reality system 1900 may also include output audio transducers 1906(A) and 1906(B). Furthermore, while not shown in FIG. 19, front rigid body 1902 may include one or more electronic elements, including one or more electronic displays, one or more inertial measurement units (IMUS), one or more tracking emitters or detectors, and/or any other suitable device or system for creating an artificial reality experience.

Artificial-reality systems may include a variety of types of visual feedback mechanisms. For example, display devices in augmented-reality system 1800 and/or virtual-reality system 1900 may include one or more liquid crystal displays (LCDs), light emitting diode (LED) displays, organic LED (OLED) displays, digital light project (DLP) micro-displays, liquid crystal on silicon (LCoS) micro-displays, and/or any other suitable type of display screen. Artificial-reality systems may include a single display screen for both eyes or may provide a display screen for each eye, which may allow for additional flexibility for varifocal adjustments or for correcting a user's refractive error. Some artificial-reality systems may also include optical subsystems having one or more lenses (e.g., conventional concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some artificial-reality systems may include one or more projection systems. For example, display devices in augmented-reality system 1800 and/or virtual-reality system 1900 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

Artificial-reality systems may also include various types of computer vision components and subsystems. For example, augmented-reality system 1800 and/or virtual-reality system 1900 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

Artificial-reality systems may also include one or more input and/or output audio transducers. In the examples shown in FIG. 19, output audio transducers 1906(A) and 1906(B) may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

While not shown in FIG. 18, artificial-reality systems may include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

As noted, artificial-reality systems 1800 and 1900 may be used with a variety of other types of devices to provide a more compelling artificial-reality experience. These devices may be haptic interfaces with transducers that provide haptic feedback and/or that collect haptic information about a user's interaction with an environment. The artificial-reality systems disclosed herein may include various types of haptic interfaces that detect or convey various types of haptic information, including tactile feedback (e.g., feedback that a user detects via nerves in the skin, which may also be referred to as cutaneous feedback) and/or kinesthetic feedback (e.g., feedback that a user detects via receptors located in muscles, joints, and/or tendons).

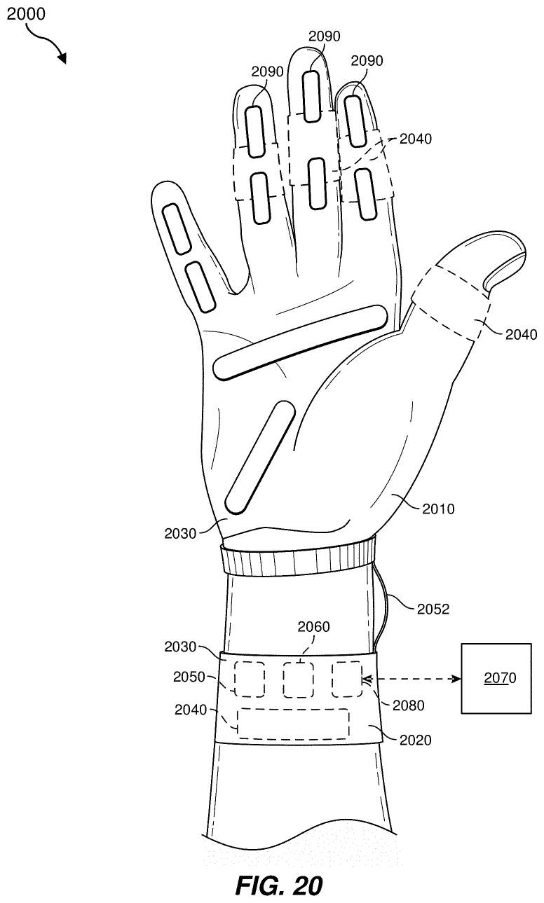

Haptic feedback may be provided by interfaces positioned within a user's environment (e.g., chairs, tables, floors, etc.) and/or interfaces on articles that may be worn or carried by a user (e.g., gloves, wristbands, etc.). As an example, FIG. 20 illustrates a vibrotactile system 2000 in the form of a wearable glove (haptic device 2010) and wristband (haptic device 2020). Haptic device 2010 and haptic device 2020 are shown as examples of wearable devices that include a flexible, wearable textile material 2030 that is shaped and configured for positioning against a user's hand and wrist, respectively. This disclosure also includes vibrotactile systems that may be shaped and configured for positioning against other human body parts, such as a finger, an arm, a head, a torso, a foot, or a leg. By way of example and not limitation, vibrotactile systems according to various embodiments of the present disclosure may also be in the form of a glove, a headband, an armband, a sleeve, a head covering, a sock, a shirt, or pants, among other possibilities. In some examples, the term “textile” may include any flexible, wearable material, including woven fabric, non-woven fabric, leather, cloth, a flexible polymer material, composite materials, etc.

One or more vibrotactile devices 2040 may be positioned at least partially within one or more corresponding pockets formed in textile material 2030 of vibrotactile system 2000. Vibrotactile devices 2040 may be positioned in locations to provide a vibrating sensation (e.g., haptic feedback) to a user of vibrotactile system 2000. For example, vibrotactile devices 2040 may be positioned against the user's finger(s), thumb, or wrist, as shown in FIG. 20. Vibrotactile devices 2040 may, in some examples, be sufficiently flexible to conform to or bend with the user's corresponding body part(s).

A power source 2050 (e.g., a battery) for applying a voltage to the vibrotactile devices 2040 for activation thereof may be electrically coupled to vibrotactile devices 2040, such as via conductive wiring 2052. In some examples, each of vibrotactile devices 2040 may be independently electrically coupled to power source 2050 for individual activation. In some embodiments, a processor 2060 may be operatively coupled to power source 2050 and configured (e.g., programmed) to control activation of vibrotactile devices 2040.

Vibrotactile system 2000 may be implemented in a variety of ways. In some examples, vibrotactile system 2000 may be a standalone system with integral subsystems and components for operation independent of other devices and systems. As another example, vibrotactile system 2000 may be configured for interaction with another device or system 2070. For example, vibrotactile system 2000 may, in some examples, include a communications interface 2080 for receiving and/or sending signals to the other device or system 2070. The other device or system 2070 may be a mobile device, a gaming console, an artificial-reality (e.g., virtual-reality, augmented-reality, mixed-reality) device, a personal computer, a tablet computer, a network device (e.g., a modem, a router, etc.), a handheld controller, etc. Communications interface 2080 may enable communications between vibrotactile system 2000 and the other device or system 2070 via a wireless (e.g., Wi-Fi, Bluetooth, cellular, radio, etc.) link or a wired link. If present, communications interface 2080 may be in communication with processor 2060, such as to provide a signal to processor 2060 to activate or deactivate one or more of the vibrotactile devices 2040.

Vibrotactile system 2000 may optionally include other subsystems and components, such as touch-sensitive pads 2090, pressure sensors, motion sensors, position sensors, lighting elements, and/or user interface elements (e.g., an on/off button, a vibration control element, etc.). During use, vibrotactile devices 2040 may be configured to be activated for a variety of different reasons, such as in response to the user's interaction with user interface elements, a signal from the motion or position sensors, a signal from the touch-sensitive pads 2090, a signal from the pressure sensors, a signal from the other device or system 2070, etc.

Although power source 2050, processor 2060, and communications interface 2080 are illustrated in FIG. 20 as being positioned in haptic device 2020, the present disclosure is not so limited. For example, one or more of power source 2050, processor 2060, or communications interface 2080 may be positioned within haptic device 2010 or within another wearable textile.

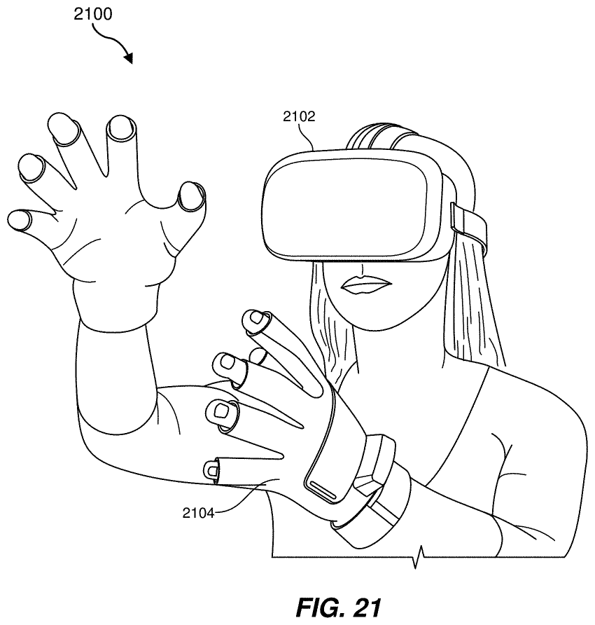

Haptic wearables, such as those shown in and described in connection with FIG. 20, may be implemented in a variety of types of artificial-reality systems and environments. FIG. 21 shows an example artificial-reality environment 2100 including one head-mounted virtual-reality display and two haptic devices (i.e., gloves), and in other embodiments any number and/or combination of these components and other components may be included in an artificial-reality system. For example, in some embodiments there may be multiple head-mounted displays each having an associated haptic device, with each head-mounted display and each haptic device communicating with the same console, portable computing device, or other computing system.

Head-mounted display 2102 generally represents any type or form of virtual-reality system, such as virtual-reality system 1900 in FIG. 19. Haptic device 2104 generally represents any type or form of wearable device, worn by a user of an artificial-reality system, that provides haptic feedback to the user to give the user the perception that he or she is physically engaging with a virtual object. In some embodiments, haptic device 2104 may provide haptic feedback by applying vibration, motion, and/or force to the user. For example, haptic device 2104 may limit or augment a user's movement. To give a specific example, haptic device 2104 may limit a user's hand from moving forward so that the user has the perception that his or her hand has come in physical contact with a virtual wall. In this specific example, one or more actuators within the haptic device may achieve the physical-movement restriction by pumping fluid into an inflatable bladder of the haptic device. In some examples, a user may also use haptic device 2104 to send action requests to a console. Examples of action requests include, without limitation, requests to start an application and/or end the application and/or requests to perform a particular action within the application.

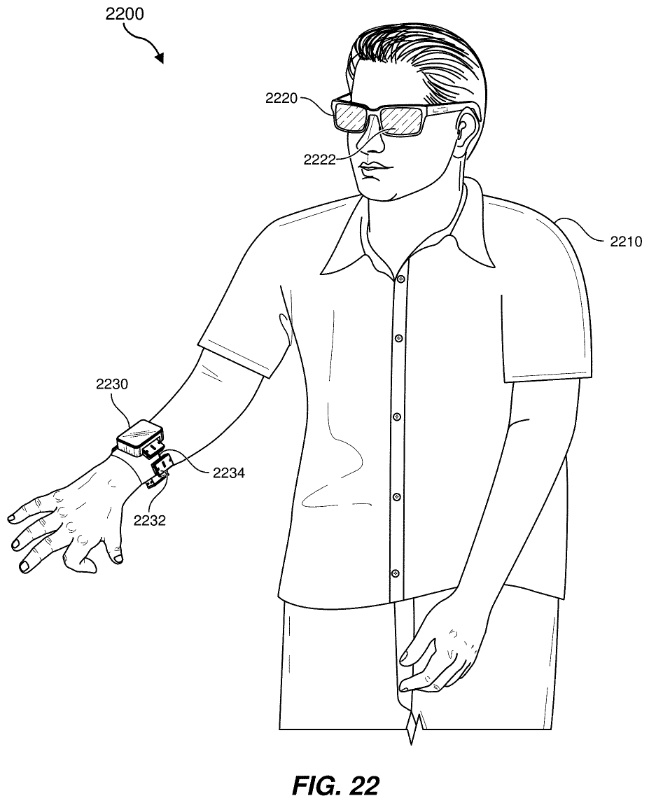

While haptic interfaces may be used with virtual-reality systems, as shown in FIG. 21, haptic interfaces may also be used with augmented-reality systems, as shown in FIG. 22. FIG. 22 is a perspective view of a user 2210 interacting with an augmented-reality system 2200. In this example, user 2210 may wear a pair of augmented-reality glasses 2220 that may have one or more displays 2222 and that are paired with a haptic device 2230. In this example, haptic device 2230 may be a wristband that includes a plurality of band elements 2232 and a tensioning mechanism 2234 that connects band elements 2232 to one another.

One or more of band elements 2232 may include any type or form of actuator suitable for providing haptic feedback. For example, one or more of band elements 2232 may be configured to provide one or more of various types of cutaneous feedback, including vibration, force, traction, texture, and/or temperature. To provide such feedback, band elements 2232 may include one or more of various types of actuators. In one example, each of band elements 2232 may include a vibrotactor (e.g., a vibrotactile actuator) configured to vibrate in unison or independently to provide one or more of various types of haptic sensations to a user. Alternatively, only a single band element or a subset of band elements may include vibrotactors.

Haptic devices 2010, 2020, 2104, and 2230 may include any suitable number and/or type of haptic transducer, sensor, and/or feedback mechanism. For example, haptic devices 2010, 2020, 2104, and 2230 may include one or more mechanical transducers, piezoelectric transducers, and/or fluidic transducers. Haptic devices 2010, 2020, 2104, and 2230 may also include various combinations of different types and forms of transducers that work together or independently to enhance a user's artificial-reality experience. In one example, each of band elements 2232 of haptic device 2230 may include a vibrotactor (e.g., a vibrotactile actuator) configured to vibrate in unison or independently to provide one or more of various types of haptic sensations to a user.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

It will be understood that when an element such as a layer or a region is referred to as being formed on, deposited on, or disposed “on” or “over” another element, it may be located directly on at least a portion of the other element, or one or more intervening elements may also be present. In contrast, when an element is referred to as being “directly on” or “directly over” another element, it may be located on at least a portion of the other element, with no intervening elements present.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to an electrode that comprises or includes indium tin oxide include embodiments where an electrode consists essentially of indium tin oxide and embodiments where an electrode consists of indium tin oxide.

What is claimed is:

1. A method comprising:
forming a polymerizable composition comprising a polymer precursor and a solid templating agent;
forming a coating of the polymerizable composition;
processing the coating to form a cured polymer material comprising a solid phase in a plurality of defined regions; and
removing at least a portion of the solid phase from the cured polymer material to form a voided polymer layer.

2. The method of claim 1, further comprising processing the polymerizable composition to form a homogeneous solution.

3. The method of claim 1, wherein removing at least a portion of the solid phase comprises subliming the templating agent at a temperature between approximately 30° C. and approximately 300° C.

4. The method of claim 1, wherein the templating agent comprises a polyaromatic hydrocarbon.

5. The method of claim 1, wherein the templating agent is selected from the group consisting of 2-naphthol, anthracene, benzoic acid, salicylic acid, camphor, saccharin, quinine, cholesterol, palmitic acid, stearic acid, acetylsalicylic acid, atropine, arsenic, piperazine, and 1,4-dichlorobenzene.

6. The method of claim 1, wherein the plurality of defined regions comprise templating material-rich domains having a maximum dimension of less than approximately 20 μm.

7. The method of claim 1, wherein removing at least a portion of the solid phase comprises sublimation.

8. The method of claim 1, wherein the voided polymer layer has an elastic modulus of from approximately 0.2 MPa to approximately 500 MPa.

9. The method of claim 1, wherein the polymerizable composition further comprises an initiator selected from the group consisting of a UV radical initiator, a thermal radical initiator, and a redox radical initiator.

10. A method comprising:
forming a homogeneous solution comprising a polymer precursor and a solid templating agent;
forming a layer of the solution on a substrate;
processing the layer to form a cured polymer material comprising discrete domains of a solid templating agent phase; and
removing at least a portion of the solid phase from the domains to form a voided polymer layer.

11. The method of claim 10, wherein the templating agent comprises a polyaromatic hydrocarbon.

12. The method of claim 10, wherein the templating agent is selected from the group consisting of 2-naphthol, anthracene, benzoic acid, salicylic acid, camphor, saccharin, quinine, cholesterol, palmitic acid, stearic acid, acetylsalicylic acid, atropine, arsenic, piperazine, and 1,4-dichlorobenzene.

13. The method of claim 10, wherein removing at least a portion of the solid phase comprises sublimation.

14. A voided polymer comprising:
a polymer matrix having a plurality of voids non-homogeneously dispersed throughout the polymer matrix.

15. The voided polymer of claim 14, wherein the voids exhibit a dendritic pattern.

16. An actuator element comprising a layer of the voided polymer of claim 14, wherein the voided polymer layer is disposed between conductive electrodes.

17. An acoustic element comprising the voided polymer of claim 14.

18. A method comprising:
introducing a vaporized reactant composition into a reaction chamber, the vaporized reactant composition comprising a polymer precursor and an organic templating agent;
forming a coating comprising the reactant composition over a substrate located within the reaction chamber; and
processing the coating to cure the polymer precursor and crystallize the organic templating agent to form a composite layer.

19. The method of claim 18, further comprising removing at least a portion of the crystallized organic templating agent from the coating to form a voided polymer layer.

20. The method of claim 18, further comprising forming a polymer layer over a surface of the composite layer.

21. The method of claim 18, further comprising pretreating substrate to locally promote crystallization of the organic templating agent.

22. The method of claim 18, further comprising forming a photoalignment layer over the substrate prior to forming the coating.

23. A composite structure comprising:
organic crystalline domains dispersed among polymer domains.

24. The composite structure of claim 23, wherein the crystalline domains are characterized by a preferred crystallographic orientation.

25. The composite structure of claim 23, wherein the polymer domains are characterized by a glassy state.

26. The composite structure of claim 23, wherein the polymer domains are mechanically elastic.
